(19) United States
(12) Patent Application Publication
(10) Pub. No.: US 2025/0218942 A1
(43) Pub. Date: Jul. 3, 2025

(54) VIA ALIGNED WITH ADJACENT INTERCONNECT LAYERS

(71) Applicant: Intel Corporation, Santa Clara, CA (US)

(72) Inventors: June Choi, Portland, OR (US); Ilya V. Karpov, Portland, OR (US); Manish Chandhok, Beaverton, OR (US); Matthew V. Metz, Portland, OR (US); Nafees Aminul Kabir, Tigard, OR (US)

(73) Assignee: Intel Corporation, Santa Clara, CA (US)

(21) Appl. No.: 18/398,101

(22) Filed: Dec. 27, 2023

(51) Int. Cl. H01L 23/528; H01L 21/768; H01L 23/522

(52) U.S. Cl. CPC H01L 23/5283; H01L 21/76841; H01L 23/5226

(57) ABSTRACT

A method comprising forming a first layer, forming a second layer over the first layer, and applying an etch material to concurrently form a first interconnect line and a second interconnect line in the first layer and side surfaces of a first via and a second via in the second layer, wherein a side surface of the first via is seamless with a side surface of the first interconnect line, wherein a side surface of the second via is seamless with a side surface of the second interconnect line, wherein the first via is adjacent to the second via.

### BACKGROUND

Integrated circuits are composed of multiple layers of materials, including interconnect layers, insulating layers, and semiconductor materials. The interconnect layers are used to create interconnections between different parts of the circuit, such as transistors, resistors, and capacitors. Interconnect layers may be connected to each other through vias. A via may be formed in an insulating layer that separates interconnect layers. The via is filled with a conductive material to create an electrical connection between lines of the interconnect layers.

### BRIEF DESCRIPTION OF THE DRAWINGS

FIG. 1 illustrates example layouts of cells comprising vias and interconnect layers, in accordance with any of the embodiments disclosed herein.

FIGS. 2A-2B illustrate via doublets, in accordance with any of the embodiments disclosed herein.

FIGS. 3A-3B illustrate perspective views of a via doublet structure, in accordance with any of the embodiments disclosed herein.

FIGS. 4A-M illustrate a flow for manufacturing a via doublet structure, in accordance with any of the embodiments disclosed herein.

FIG. 5A-G illustrates a flow for manufacturing a via doublet structure, in accordance with any of the embodiments disclosed herein.

FIG. 6 illustrates a via doublet structure with partial misalignment, in accordance with any of the embodiments disclosed herein.

FIG. 7 illustrates a method for manufacturing a via doublet structure, in accordance with any of the embodiments disclosed herein.

FIG. 8 provides a schematic illustration of a cross-sectional view of an example integrated circuit device, in accordance with any of the embodiments disclosed herein.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIGS. 11A-11D are perspective views of example planar, FinFET, gate-all-around, and stacked gate-all-around transistors.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

FIG. 14 illustrates a stage of an alternative flow for manufacturing a via doublet structure, in accordance with any of the embodiments disclosed herein.

FIG. 15 illustrates a stage of an alternative flow for manufacturing a via doublet structure, in accordance with any of the embodiments disclosed herein.

### DETAILED DESCRIPTION

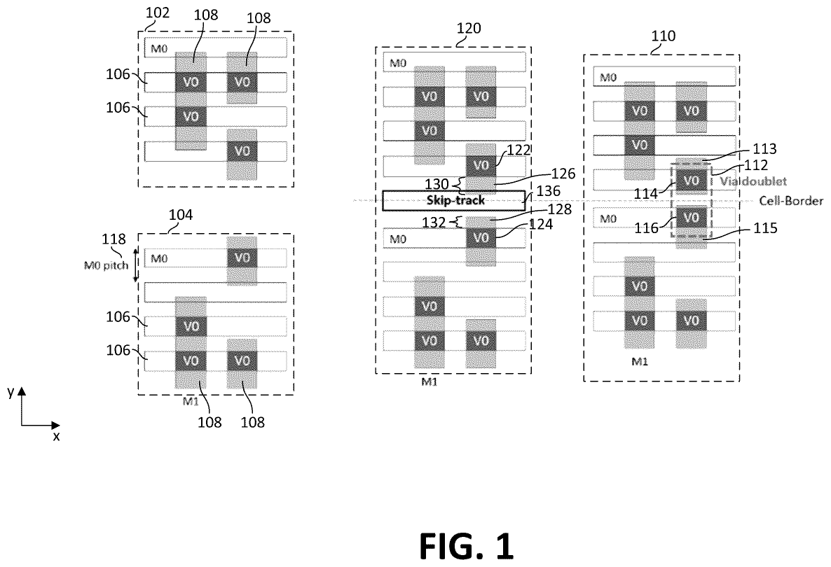

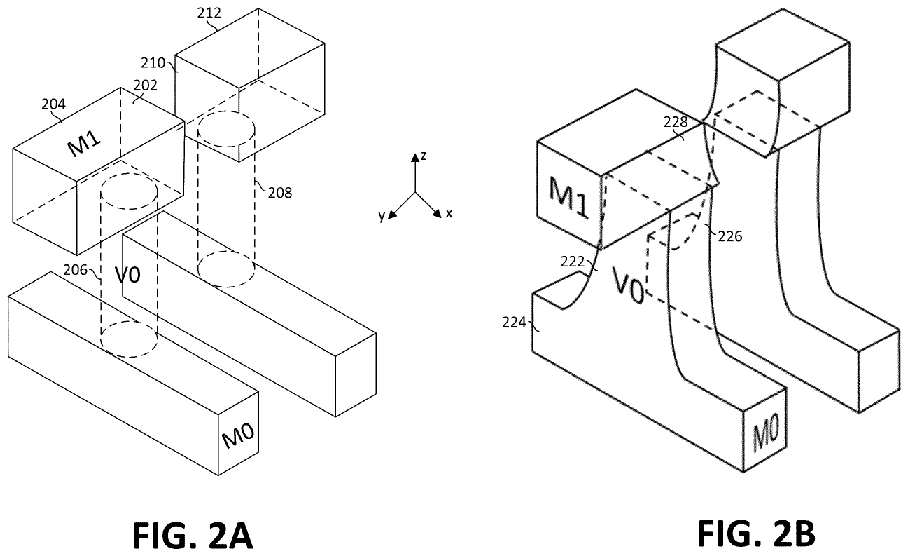

FIG. 1 illustrates example layouts of cells comprising vias and interconnect layers, in accordance with any of the embodiments disclosed herein. In this example, a first cell 102 is to be placed adjacent to a second cell 104. The cells include a plurality of interconnect lines 106 (referred to herein as tracks) of a conductive material in a first interconnect layer. In this example, this interconnect layer is a first metal layer (M0). The tracks 106 each have a length that extends in a first direction (e.g., the x direction), a width in a direction orthogonal to the first direction (e.g., the y direction). The lengths of the lines may vary, but are generally longer than the respective widths.

The cells also include a plurality of interconnect lines 108 (also referred to herein as tracks) of a conductive material in a second interconnect layer above the first interconnect layer. In this example, this interconnect layer is a second metal layer (M1). The tracks 108 each have a length that extends in the second direction (e.g., the y direction) and a width in the first direction (e.g., the x direction). Again, the lengths of the lines may vary, but are generally longer than the respective widths.

A track 106 of the first metal layer may be electrically connected to a track 108 of the second metal layer through a via (VO) that has a height that extends in a direction substantially orthogonal to the first direction and the second direction (e.g., the z direction).

A via doublet is a via design configuration in which a pair of vias that are on different nets that are electrically isolated from each other are placed next to each other. Layout 110 depicts a via doublet 112 in which a via 114 of cell 102 is placed adjacent to a via 116 of cell 104 when cells 102 and 104 are abutted together in a design. In this example, the portions of the tracks 113 and 115 that are coupled to the respective vias 114 and 116 align relatively well with the via side surfaces and the vias are thus able to be placed next to each other at the standard M0 pitch 118 (the distance between corresponding points on adjacent interconnect lines).

At tight interconnect pitches (e.g., when the M0 pitch 118 between corresponding points on adjacent lines is 20 nm or less), it may be extremely difficult, if not impossible, to fabricate a via doublet using a classical damascene process, since the vias are too close to print, etch, and fill. This results in the use of a skip-track to provide sufficient distance between adjacent vias. For example, layout 120 of FIG. 1 also depicts cell 102 placed adjacent to cell 104, such that via 122 of cell 102 is placed adjacent to via 124 of cell 104. However, because the vias do not align closely with the M1 tracks 126, 128 (e.g., see overhangs 130, 132), a skip-track 136 must be placed between cell 102 and cell 104 to avoid electrical shorting (e.g., between the M1 tracks and/or the vias themselves). The skip-track can be, e.g., an actual conductive track (e.g., made of the same material as the other tracks) or an empty area (e.g., a dielectric). The skip-track may result in a spacing of two times the M0 pitch between the M0 tracks coupled to the vias.

The via doublet is often preferred at cell borders for area savings, as it enables two separate cell designs to be abutted with no skip-tracks, thus conserving area that would otherwise remain unused. This layout is enabled by a structure in which (at least some of) the side surfaces of the vias are aligned with the respective side surfaces of the top and bottom interconnect lines (e.g., M0 and M1 tracks). This alignment may be a result of common etching steps for the tracks and the vias and/or by the patterning for the upper track functioning as a mask for the via during etching as will be explained in further detail below.

FIGS. 2A-2B illustrate via doublets, in accordance with any of the embodiments disclosed herein. FIG. 2A includes a representation of an idealized via doublet based on a standard damascene manufacturing process. In this figure, the side surface 202 of M1 track 204 is well aligned with the inner vertical edge of via 206 (the edge closest to via 208) and the side surface 210 of M1 track 212 is well aligned with the inner vertical edge of via 208 (the edge closest to via 206). However, in the real world, such close alignment is not achievable using a standard damascene manufacturing process, and one or more of the vias or the M1 tracks may be shifted in the x and/or y direction. Thus, the vias and/or the M1 tracks may end up too close together and a skip-track may be needed (and thus the M0 tracks coupled to the vias and the vias themselves would be separated by twice the M0 pitch).

FIG. 2B illustrates a via doublet that may be manufactured by techniques described herein. In this embodiment, side surface 222 of a via is self-aligned with the surface 224 of the M0 track. Indeed, in some embodiments, the via VO may be monolithic with the M0 track and the surfaces 222 and 224 may be formed during the same etch step (e.g., the side surfaces may be subtractively defined concurrently with the same etch mask).

Thus, surfaces 222 and 224 may generally be in the same plane at the interface between the M0 track and the via VO (thus at least a portion of the surfaces 222 and 224 may be in the same plane). Thus, the contour from surface 222 to surface 224 may be seamless.

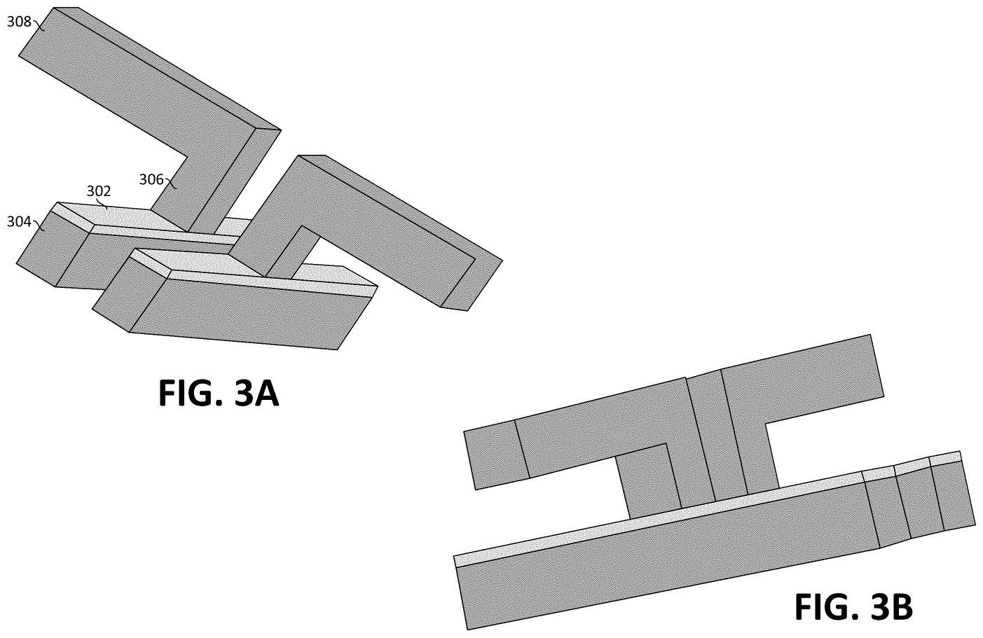

In some instances, a conductive etch stop layer may be formed as part of the M0 track (e.g., over another conductive material of the M0 track and underneath the via), and a side surface of the etch stop layer may also be self-aligned with the surface 222 and surface 224 (this side surface of the etch stop layer may also be shaped during the etch step used to shape surfaces 222 and 224). Such an instance is depicted in FIGS. 3A and 3B which are perspective views of a via doublet. Conductive etch stop layer 302 is formed on M0 track 304 (and may be considered part of the M0 track 304) and is in contact with via 306 which couples M1 track 308 to M0 track 304.

In various embodiments, the via is monolithic to the M0 track and is carved out (etched) from a taller stack which includes the M0 material, a conductive etch stop layer, and the via material.

Returning again to FIG. 2, the side surfaces that are opposite to side surfaces 222 and 224 may have the same characteristics (e.g., they may be aligned in a similar manner) as side surfaces 222 and 224. Accordingly, the via is aligned very well (e.g., perfectly) with the M0 track, ensuring that the distance between adjacent vias will be substantially equal to the M0 track pitch.

The adjoining side surface 226 of the via may have a similar relationship with the side surface 228 of the M1 track. That is, the side surface 226 is self-aligned with the side surface 228. The surfaces that are opposite surfaces 226 and 228 may have the same characteristics (e.g., may be aligned similarly) as surfaces 226 and 228. Accordingly, the via is aligned very well (e.g., perfectly) with the M1 track at these surfaces. Such close alignment may be achieved by using the same etch mask when forming these surfaces via an etch process.

The side surfaces shown and/or described as being aligned together may belong to the same surface plane at the interface of these side surfaces (and may be in the same surface plane along at least a portion of the surfaces and in some cases a substantial portion of these surfaces). For surfaces that are aligned together, there may be no discernable lateral offset (e.g., along the x-axis or y-axis depending on the particular surfaces) between the side surfaces at the interface of the side surfaces. The side surfaces may be contiguous with each other and/or have material homogeneity with each other.

In various embodiments, the cross section (e.g., in the x-y plane) of the via may be substantially rectangular along its height (or at least at the bottom of the via where it interfaces with M0 and/or the top of the via where it interfaces with M1).

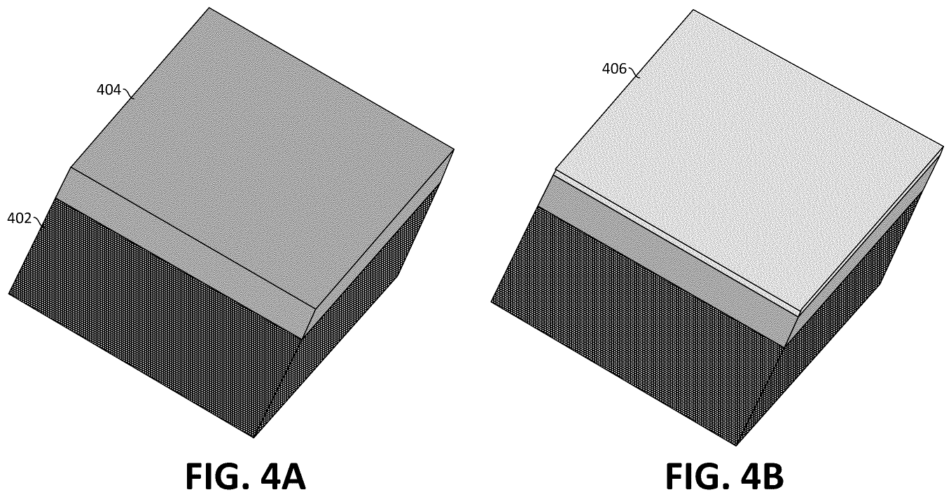

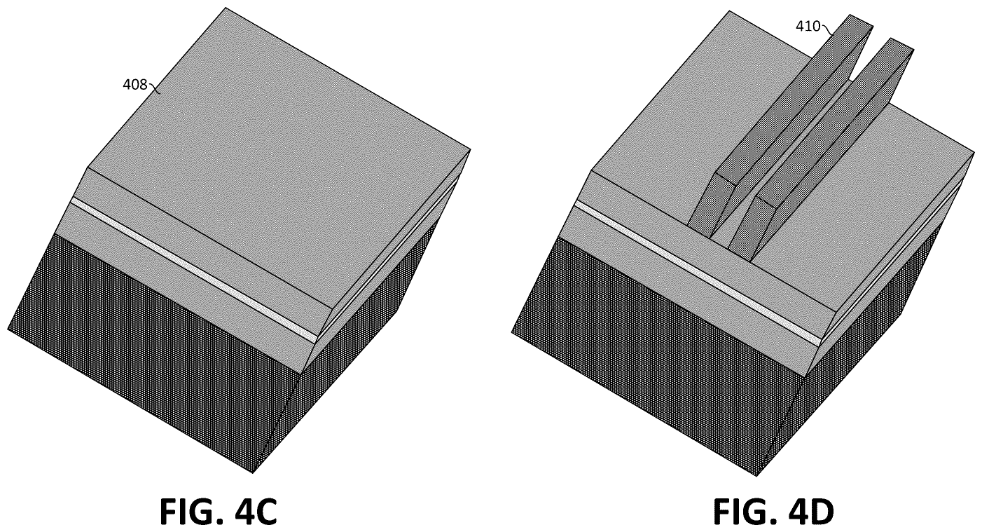

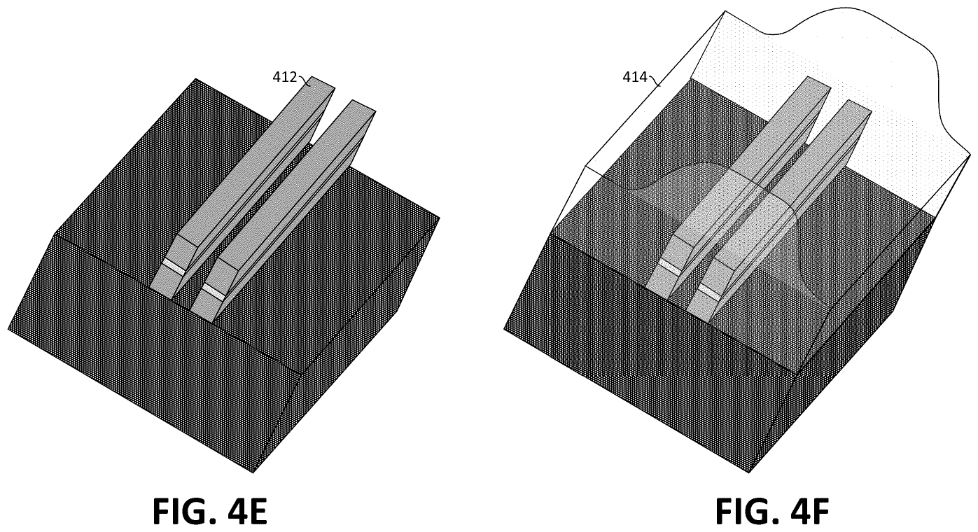

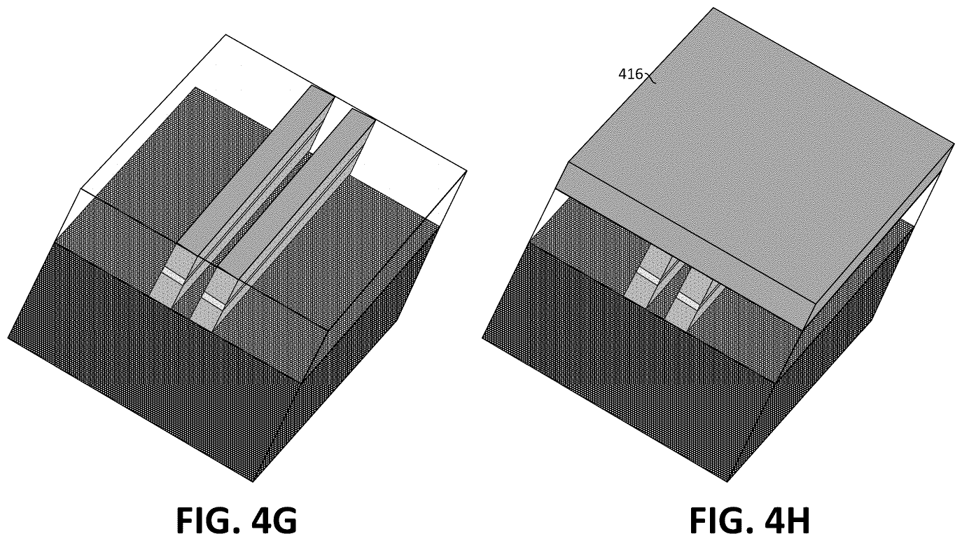

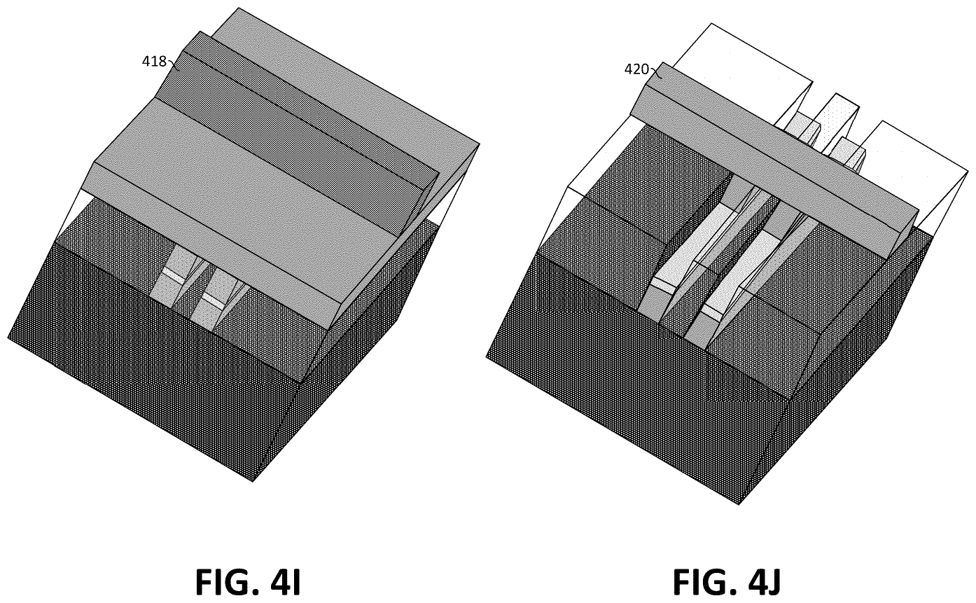

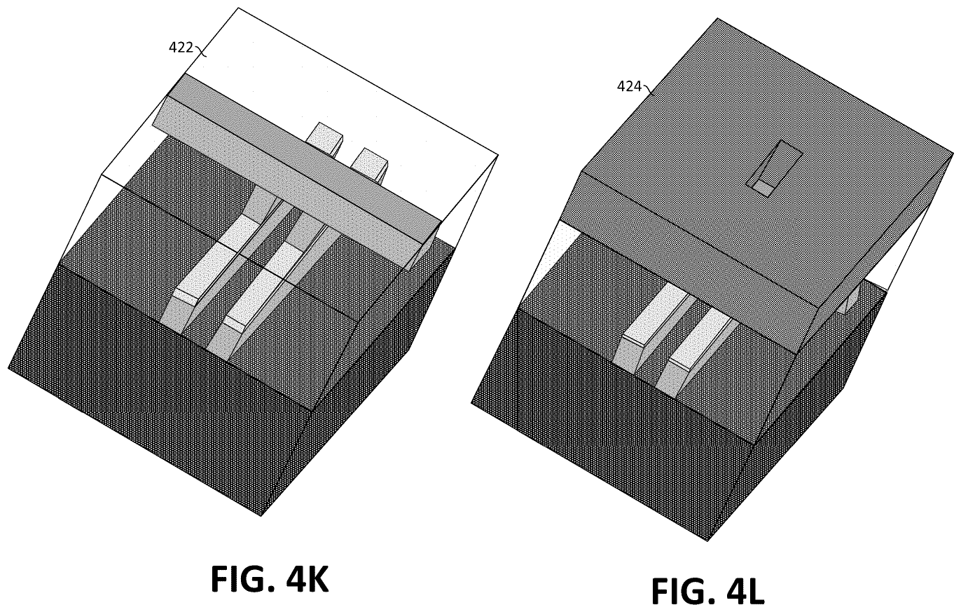

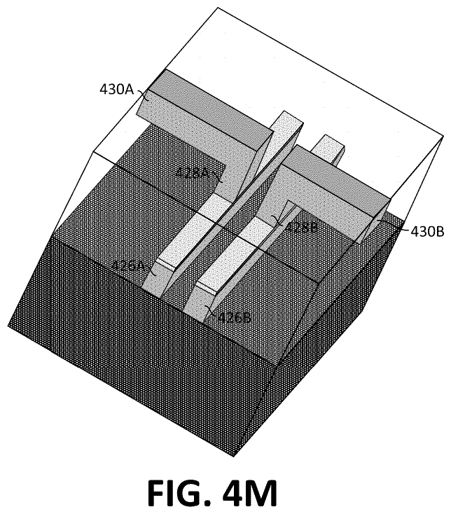

FIGS. 4A-M illustrate a flow for manufacturing a via doublet structure, in accordance with any of the embodiments disclosed herein. As depicted in FIG. 4A, an interconnect layer 404 is formed on a base portion 402. The base portion may comprise any suitable materials or components, such as one or more dielectric materials, transistors, other semiconductor devices (e.g., diodes, memory devices), magnetic memory devices, ferro-electric memory devices, or other devices. In some embodiments, the base portion may comprise a planarized surface including dielectric material and a surface of conductive contacts coupled to terminals of devices in an underlying device layer of the base portion 402. Lines (e.g., tracks) of the interconnect layers described herein may connect to these conductive contacts.

The interconnect layer 404 may comprise any suitable conductive material, such as a metal or metal alloy comprising one or more of ruthenium, molybdenum, tungsten, titanium, aluminum, copper, cobalt, or other suitable metal. In some embodiments, the conductive material may comprise a carbon-based material with good electrical conductivity, such as graphite or carbon nanotubes. The interconnect layer 404 may comprise a material that is amenable to subtractive patterning through an etch process. In some embodiments, the interconnect layer 404 may be a M0 layer.

Formation of the interconnect layer 404 (or other subsequent layers described herein) may be accomplished using any suitable deposition technique or other suitable technique, such as one or more of physical vapor deposition (PVD), chemical vapor deposition (CVD), plating, or layer transfer/bonding techniques.

As depicted in FIG. 4B, an etch stop layer 406 is then formed on the interconnect layer 404. The etch stop layer 406 comprises one or more conductive materials with the proper etch selectivity, such as one or more metals. As one example, when the interconnect lines (e.g., M0 and M1 tracks) and corresponding vias comprise ruthenium, the etch stop layer 406 may comprise tungsten, or vice versa. In other embodiments, the etch stop layer 406 may comprise titanium nitride, tantalum, or tantalum nitride, or other suitable conductive material.

As depicted in FIG. 4C, a via layer 408 is formed on the etch stop layer 406. The via layer may comprise a conductive material, such as any of the conductive materials described above in connection with interconnect layer 404. The via layer 408 may be the same material as the interconnect layer 404 or it may be a different material.

As depicted in FIG. 4D, patterned material 410 is formed on the via layer 408. The patterned material 410 may be any suitable material used to protect the area underneath the patterned material from being etched away. For example, the patterned material 410 may comprise one or more hard mask layers (e.g., silicon nitride, silicon oxide, or other suitable hard mask material), a photoresist material, and/or other suitable material. In various embodiments, single patterning or multiple patterning techniques may be employed in this operation or in other patterning operation described herein to define one or more masks around which etching may be performed. The patterned material 410 defines the pattern for the M0 tracks to be coupled to the via doublet as well as side surfaces of the vias that are to be aligned with the side surfaces of the tracks.

As depicted in FIG. 4E, etching is then performed to remove the portions of the interconnect layer 404, etch stop layer 406, and via layer 408 that are not protected by (e.g., underneath) the patterned material 410. Any suitable etching process may be performed, such as one or more anisotropic plasma (reactive ion) etch processes to subtractively define the M0 tracks and the side surfaces of the vias. In an embodiment in which the via layer 408 and interconnect layer 404 comprise ruthenium, the ruthenium may be oxidized, and then the ruthenium oxide may be etched with chlorine. For sidewall passivation, nitrogen, carbonyl sulfide, and a hydrofluorocarbon (CHₓF_{y}) (or other suitable chemistries) may be used to maintain the hardmask retention by increasing selectivity during the etch to maintain a straight sidewall and prevent from grain boundary attack from the side. the material to be etched. The etching process results in formation of strips 412 of interconnect layer 404, etch stop layer 406, and via layer 408.

As depicted in FIG. 4F, an interlayer dielectric (ILD) 414 is then formed over the base portion 402 and the strips 412. Any suitable ILD may be used, such as silicon dioxide, silicon nitride, silicon oxynitride, a low-k dielectric, or other suitable dielectric material. In the embodiment depicted, the ILD 414 may be deposited substantially conformally over the base portion 402 and the strips 412.

As depicted in FIG. 4G, chemical mechanical polishing (CMP) or planarization may then be performed to smooth out the top surface of the structure to prepare for fabrication of a subsequent interconnect layer. The ILD may be planarized with a top surface of the strips 412.

As depicted in FIG. 4H, an additional interconnect layer 416 is formed on the ILD 414 and the top of the strips 412 (and in contact with the top of the via layer 408 portion of the strips). In various embodiments, the interconnect layer 416 may comprise a conductive material, such as any of the conductive materials described above in connection with interconnect layer 404. The interconnect layer 416 may be the same material as the interconnect layer 404 or it may be a different material. Similarly, the interconnect layer 416 may be the same material as the via layer 408 or it may be a different material.

In some embodiments, interconnect layer 416 may comprise cobalt or tungsten while interconnect layer 404 comprises ruthenium or molybdenum.

As depicted in FIG. 4I, patterned material 418 is formed on interconnect layer 416. The patterned material 418 may be any suitable material used to protect the area underneath the patterned material from being etched away. For example, the patterned material 410 may comprise one or more hard mask layers, a photoresist material, and/or other suitable material. In various embodiments, the patterned material 418 may be the same as the patterned material 410 (e.g., if the same material is used for interconnect layer 416 and via layer 408 and/or interconnect layer 404) or different in any suitable aspect.

As depicted in FIG. 4J, etching is then performed to remove the portions of the interconnect layer 416 (e.g., down to the ILD) that are not protected by (e.g., underneath) the patterned material 410. This results in formation of a strip 420 of interconnect layer 416. The etching also removes the portions of the via layer 408 (down to the etch stop layer 406) that are not protected by (e.g., underneath) the patterned material 418. In various embodiments, the etch process may be similar to the etch process performed earlier (e.g., if the same material is used for interconnect layer 416 and via layer 408 and/or interconnect layer 404) or different in any suitable aspect.

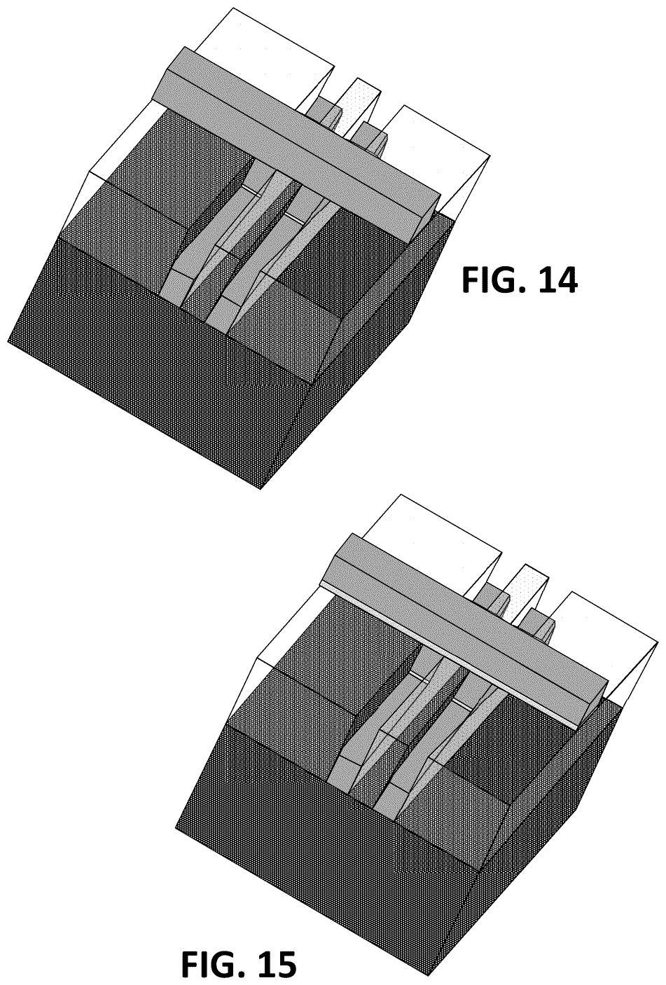

In various embodiments, the etch stop layer 406 stops the etching at precisely the top of the remaining etch stop layer 406 across an entire wafer (e.g., a 300 mm wafer). This may provide insensitivity to interconnect layer thickness variation. In various embodiments, the etch process may include application of a first etch material to remove portions of the interconnect layer 416 and via layer 408 and stop on the etch stop layer 406 and then a second etch material to remove the exposed etch stop layer 406. Although the embodiment of FIG. 4J does not depict application of this second etch material to remove the etch stop layer 406, such an embodiment is depicted in FIG. 14 (and in alternative embodiments could undergo the same processing steps as described in connection with FIGS. 4K-4M).

As depicted in FIG. 4K, another ILD layer 422 is formed and then CMP is performed to smooth out the top surface of the structure. Although not shown, the ILD layer 422 may be formed substantially conformally on top of the structure shown in FIG. 4J and then planarized along with the top of the strip 420 to the structure shown in FIG. 4K.

As depicted in FIG. 4L, patterned material 424 is formed over the top of the ILD layer 422 and the top of the strip 420. Again, the patterned material may be the same as the previous patterning materials or different in any suitable aspect.

As depicted in FIG. 4M, etching is then performed to remove the portion of the interconnect layer 416 of the strip 420 that is that is not protected by the patterned material 424. In various embodiments, the etch process may be similar to either of the etch processes performed earlier or different in any suitable aspect. This results in isolation of portions of the strip 420, thus forming tracks 430A and 430B. The resulting structure now has first interconnect layer (e.g., M0) tracks 426A and 426B, second interconnect layer (e.g., M1) tracks 430A and 430B, and vias 428A and 428B.

In some instances, the patterning and etching shown in FIGS. 4L and 4M may be omitted and the doublet structure may be as shown in FIG. 4K. For example, such an embodiment may be used when a M1 track is to be electrically connected to two M0 tracks.

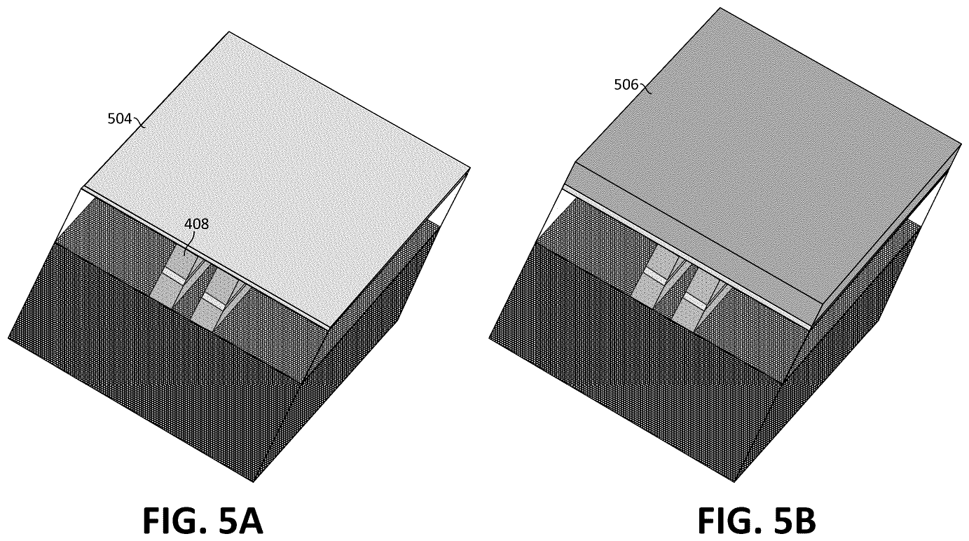

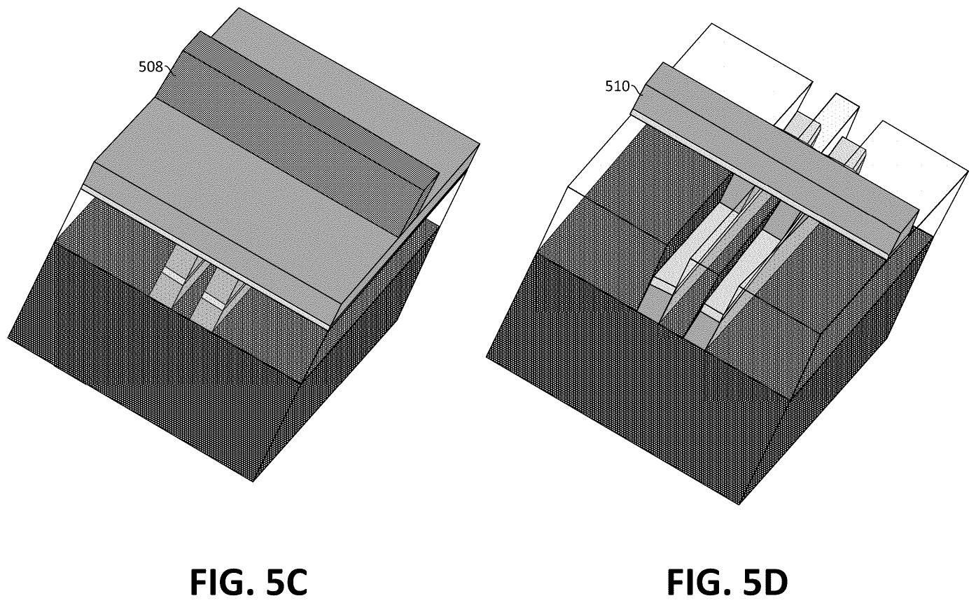

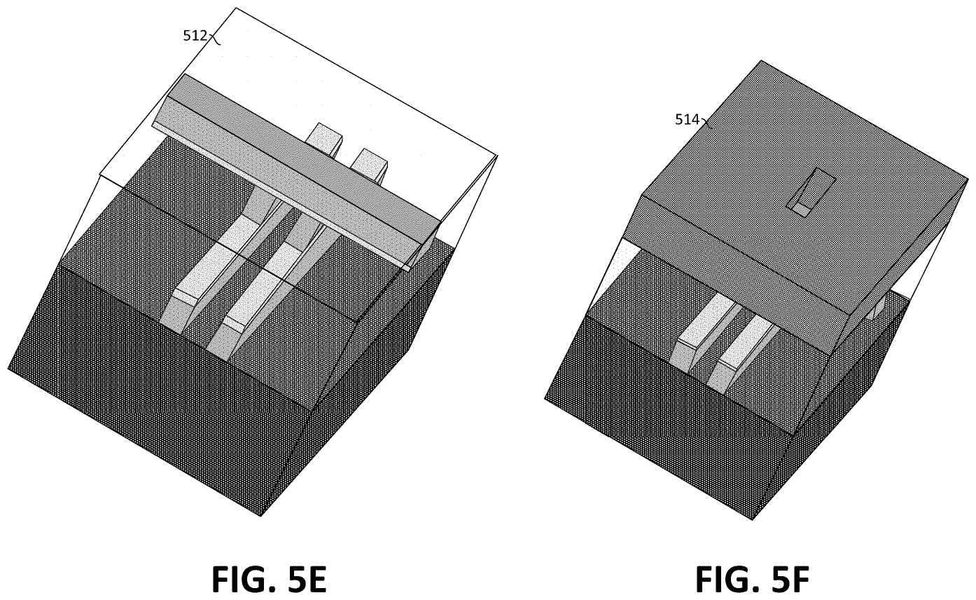

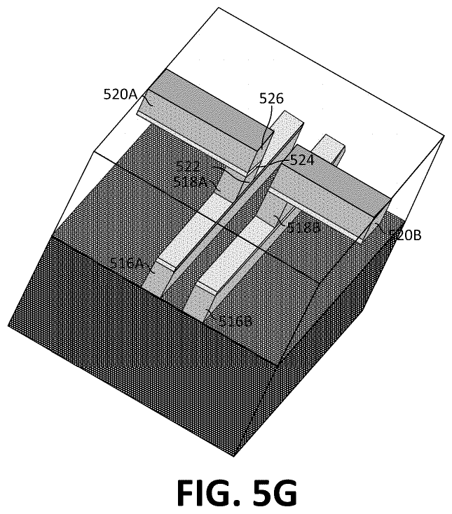

FIG. 5A-G illustrates a flow for manufacturing a via doublet structure, in accordance with any of the embodiments disclosed herein. This flow may proceed after the operations depicted in FIGS. 4A-G as an alternative to the operations depicted in FIGS. 4H-M.

As depicted in FIG. 5A, instead of forming the additional interconnect layer (e.g., the M1 layer) on the ILD and the via layer of the strips, a conductive etch stop layer 504 is first formed on the ILD and the top of the strips (and in contact with the top of the via layer 408 portion of the strips). Similar to the etch stop layer 406, the etch stop layer 504 comprises one or more conductive materials with the proper etch selectivity, such as one or more metals. In one embodiment, the etch stop layer 504 comprises the same material as the etch stop layer 406. In other embodiments, the etch stop layers may comprise different materials.

As depicted in FIG. 5B, the additional interconnect layer 506 is then formed on the etch stop layer 504. The additional interconnect layer 506 may have any suitable characteristics of interconnect layer 416.

As depicted in FIG. 5C, patterned material 508 is then formed on interconnect layer 506. The patterned material 508 may be any suitable material used to protect the area underneath the patterned material from being etched away and may have any suitable characteristics of patterned material 418.

As depicted in FIG. 5D, etching is then performed to remove the portions of the interconnect layer 506 and the etch stop 504 layer (down to the ILD) that are not protected by (e.g., underneath) the patterned material 508. This results in formation of a strip 510 of interconnect layer 506 and etch stop layer 504. The etching also removes the portions of the via layer 408 (down to the etch stop layer 406) that are not protected by (e.g., underneath) the patterned material 508.

In some embodiments, the exposed portions (e.g., the portions not underneath the vias) of the lower etch stop layer may also be removed during this etch process. Although the embodiment of FIG. 5D does not depict removal of the etch stop layer 504 by application of a second etch material, such an embodiment is depicted in FIG. 15 (and in alternative embodiments could undergo the same processing steps as described in connection with FIGS. 5E-5G).

As depicted in FIG. 5E, another ILD layer 512 is formed and then CMP is performed to smooth out the top surface of the structure. Although not shown, the ILD layer 512 may be formed substantially conformally on top of the structure shown in FIG. 5D and then planarized along with the top of the strip 510 to the structure shown in FIG. 5E.

As depicted in FIG. 5F, patterned material 514 is formed over the top of the ILD layer 512 and the top of the strip 510.

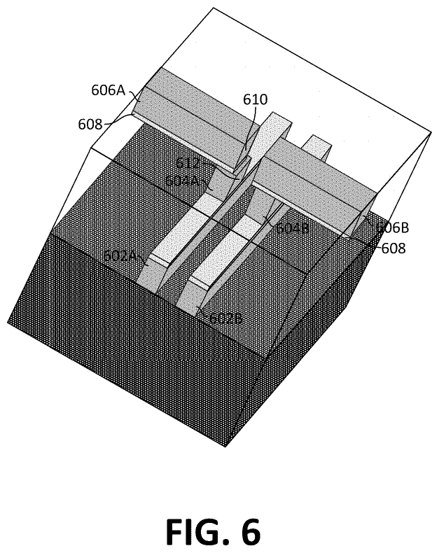

As depicted in FIG. 5G, etching is then performed to remove the portion of the interconnect layer 506 and the etch stop layer 504 of the strip 510 (e.g., down to the ILD) that is not protected by the patterned material 514. In one example, the etch stop layer 504 may comprise tungsten and may protect a portion of the via layer comprising ruthenium from an etch process that removes a portion of the interconnect layer 506 (e.g., as explained in conjunction with FIG. 6).

The etching results in electrical isolation of portions of the strip 510, thus forming tracks 520A and 520B. The resulting structure now has first interconnect layer (e.g., M0) tracks 516A and 516B, second interconnect layer (e.g., M1) tracks 520A and 520B, and vias 518A and 518B.

In this embodiment, the patterning is performed in an ideal manner, such that the side surface 522 of the via 518A aligns with the side surface 524 of the etch stop layer and the side surface 526 of the track 520A. A similar alignment is present on the corresponding surfaces of the other via 518B, etch stop layer, and track 520B. In various embodiments, when the patterned material 514 is misaligned with the desired etch area, the etch stop layer 504 may protect the via from the etch, thus preserving the dimensions of the via and the spacing between the vias of the via doublet as illustrated in FIG. 6. Such dimensions and spacing may be substantially similar for various via doublets across an integrated circuit. The dimensions at the top of the via may be preserved as the via is only exposed to the etch when the etch stop layer 608 is etched, and the etch stop layer may have very high selectivity to the via material, thus preserving the via during the etch process.

FIG. 6 illustrates a via doublet structure with partial misalignment, in accordance with any of the embodiments disclosed herein. Such a structure may result from misalignment of the patterned material 514.

As depicted in this embodiment, the side surface 610 of the track 606A is misaligned with the side surface 612 of the via 604A (such that there is a lateral offset between the two side surfaces), but the etch stop layer 608 has protected the via and preserved the dimensions of the via 604A and the spacing of the vias 604A and 604B.

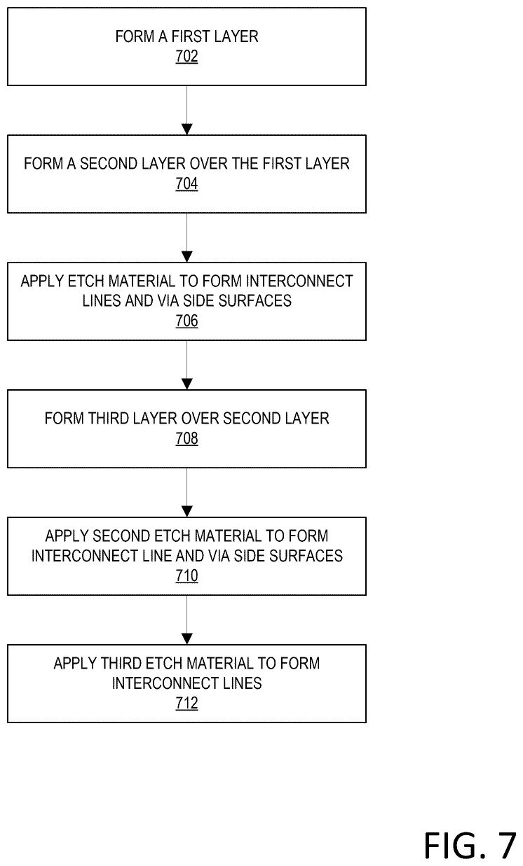

FIG. 7 illustrates a method for manufacturing a via doublet structure. At 702 a first layer is formed. The first layer may be an interconnect layer and may comprise a conductive material. In some embodiments, the first layer may also comprise a conductive etch stop material placed over the conductive material.

At 704, a second layer is formed over the first layer. The second layer may comprise a conductive material (which may be the same material as the conductive material of the first layer or a different conductive material).

At 706, an etch material is applied to the first layer and second layer to form interconnect lines (e.g., M0 lines) and side surfaces of vias (e.g., of a via doublet to be formed).

At 708, a third layer is formed over the second layer. The third layer may comprise a conductive material (which may be the same material as the conductive material of the first layer and/or the conductive material of the second layer or may be a different conductive material).

At 710, a second etch material is applied to form an interconnect line and via side surfaces (e.g., of the via doublet). At this stage, the interconnect line is connected to both vias of the via doublet. At 712, a third etch material is applied to form two interconnect lines from the interconnect line formed at 710. The etch electrically isolates the interconnect lines and respective vias of the via doublet.

While the flows and structures described herein depict particular layers, in other embodiments, additional layers may be present in between any of the adjacent layers shown or layers (e.g., some of the etch stop layers) may be omitted. Thus, recitation of a first layer formed on a second layer may also contemplate embodiments in which the first layer is formed above the second layer with one or more other layers formed in between the first layer and second layer.

Although a subtractive process is described herein, in other embodiments, at least a portion of the via doublet structure is formed using a damascene process. For example, trenches may be carved in a dielectric material and then filled with the conductive tracks or vias and then polished. For example, a damascene process may be used to fabricate strips 412, but omitting the etch stop layer in between the interconnect layer 404 and via layer 408 (e.g., the interconnect layer 404 and the via layer 408 portions of the strips 412 may be formed of the same material in the same process step).

Although some embodiments herein have been described with respect to vias between M0 and M1 tracks, other embodiments contemplate application of the teachings herein for vias between any suitable conductive tracks, such as vias between any suitable adjacent metal layers (e.g., M1 and M2, M2 and M3, etc.).

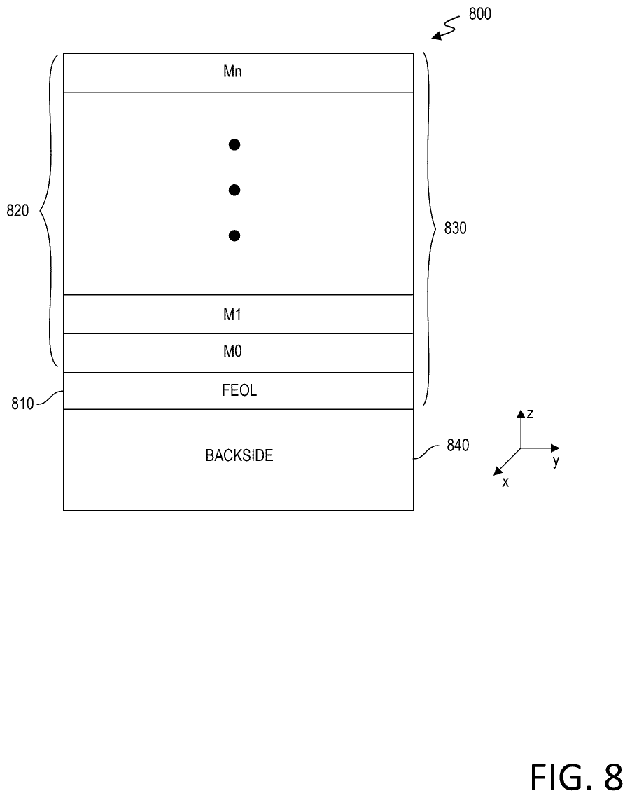

FIG. 8 provides a schematic illustration of a cross-sectional view of an example integrated circuit device (e.g., a chip) 800. The IC device 800 may include transistors as well as other circuit elements (e.g., resistors, diodes, capacitors, inductors, etc.).

As shown in FIG. 8, the IC device 800 may include a front side 830 comprising a front-end-of-line (FEOL) 810 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 810 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 820.

The front side 830 of the IC device 800 also includes a BEOL 820 including various metal interconnect layers (e.g., metal 0 through metal n, where n is any suitable integer). Various metal layers of the BEOL 820 may be used to interconnect the various inputs and outputs of the FEOL 810.

Generally speaking, each of the metal layers of the BEOL 820, e.g., each of the layers M0-Mn shown in FIG. 8, may include a via portion (any of which may comprise a via doublet as described herein) and a trench/interconnect portion. Typically, the trench portion of a metal layer is above the via portion, but, in other embodiments, a trench portion may be provided below a via portion of any given metal layer of the BEOL 820. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 820, e.g., layers M0-Mn shown in FIG. 8, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 800 may also include a backside 840. For example, the backside 840 may be formed on the opposite side of a wafer from the front side 830. In various embodiments, the backside 840 may include any suitable elements to assist operation of the IC device 800. For example, the backside 840 may include various metal layers to deliver power to logic of the FEOL 810.

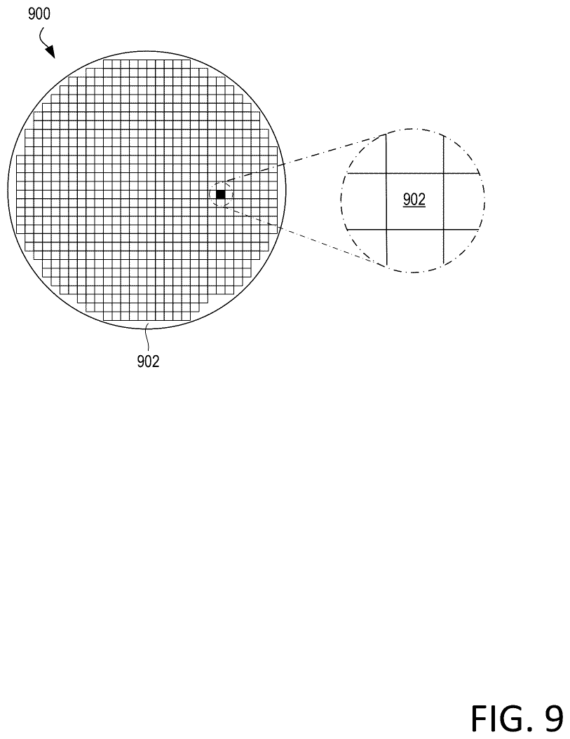

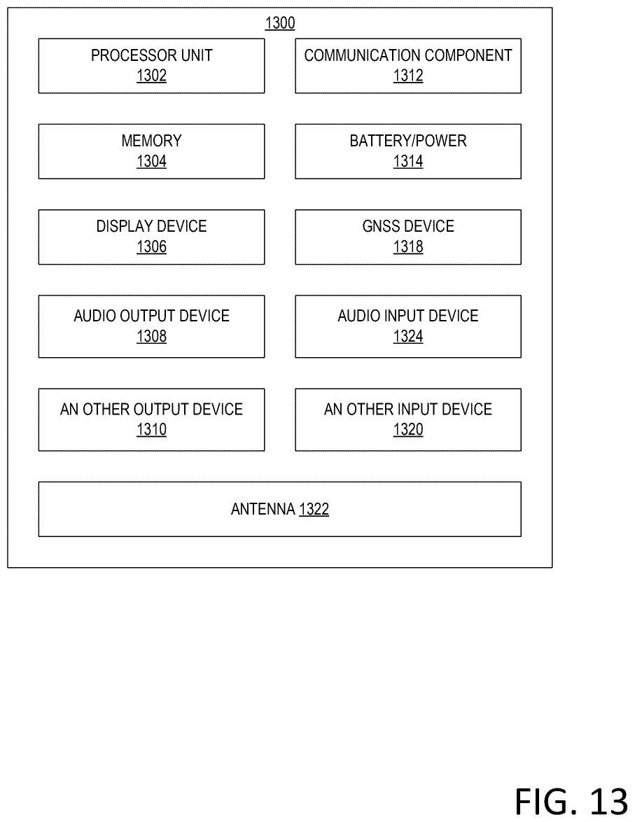

FIG. 9 is a top view of a wafer 900 and dies 902, wherein individual dies may include via doublets as disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors, supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1302 of FIG. 13) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 900 that include other dies, and the wafer 900 is subsequently singulated.

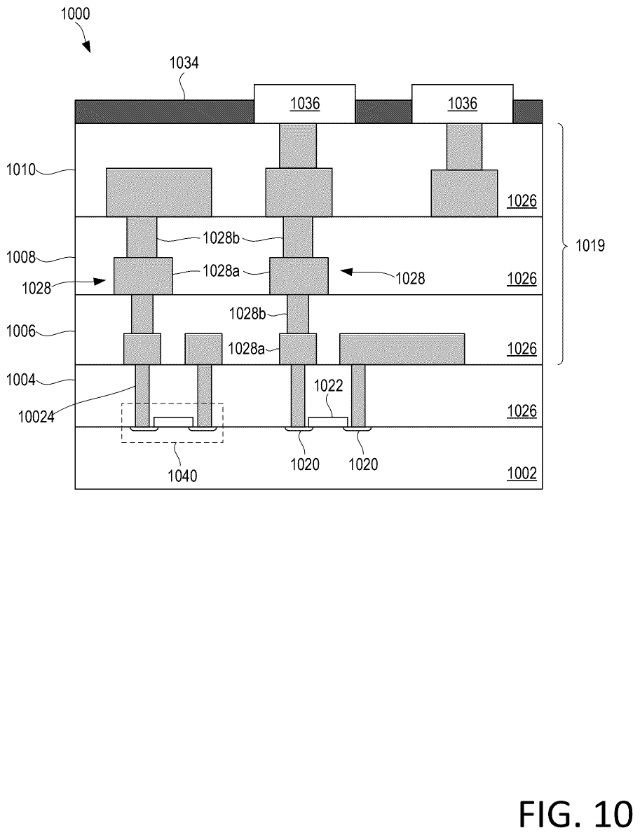

FIG. 10 is a cross-sectional side view of an integrated circuit device 1000 that may include via doublets as disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

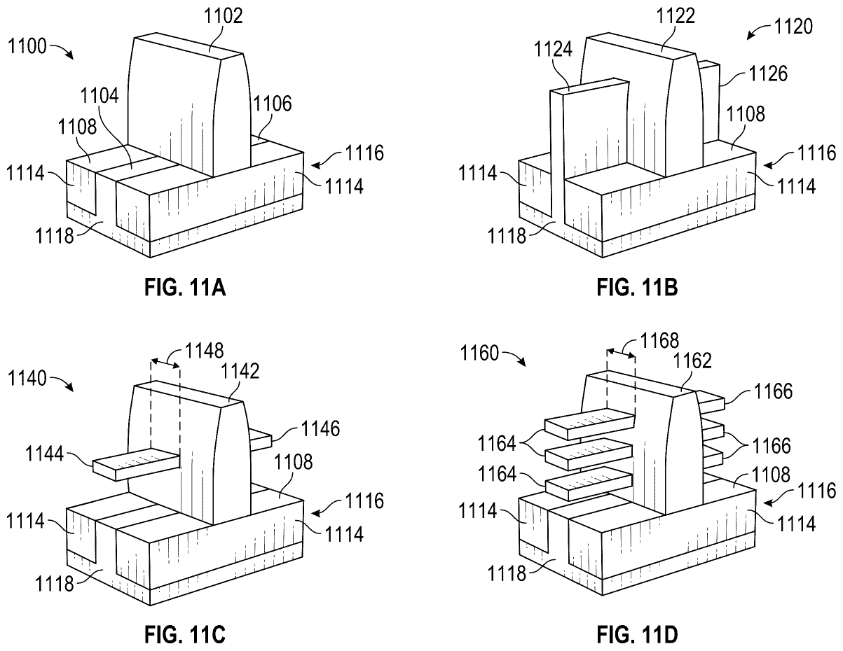

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor 1140 comprising a gate 1142 that controls current flow between a source region 1144 and a drain region 1146. The transistor 1140 is non-planar in that the source region 1144 and the drain region 1146 are elevated from the substrate surface 1128.

FIG. 11D is a perspective view of a GAA transistor 1160 comprising a gate 1162 that controls current flow between multiple elevated source regions 1164 and multiple elevated drain regions 1166. The transistor 1160 is a stacked GAA transistor as the gate controls the flow of current between multiple elevated S/D regions stacked on top of each other. The transistors 1140 and 1160 are considered gate-all-around transistors as the gates encompass all sides of the semiconductor portions that extends from the source regions to the drain regions. The transistors 1140 and 1160 can alternatively be referred to as nanowire, nanosheet, or nanoribbon transistors depending on the width (e.g., widths 1148 and 1168 of transistors 1140 and 1160, respectively) of the semiconductor portions extending through the gate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of or comprise a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 (e.g., lines) may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 0 or “M0”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b (which in some embodiments may include via doublets as described herein) of the first interconnect layer 1006 may be coupled with the lines 1028a of a second interconnect layer 1008.

The second interconnect layer 1008 (referred to as Metal 1 or “M1”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 2 or “M2”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the integrated circuit device (e.g., die) 1000, and the metallization stack 1019 can be used to route I/O signals from the conductive contacts 1036 to transistors 1040 and any other components integrated into the integrated circuit device (e.g., die) 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

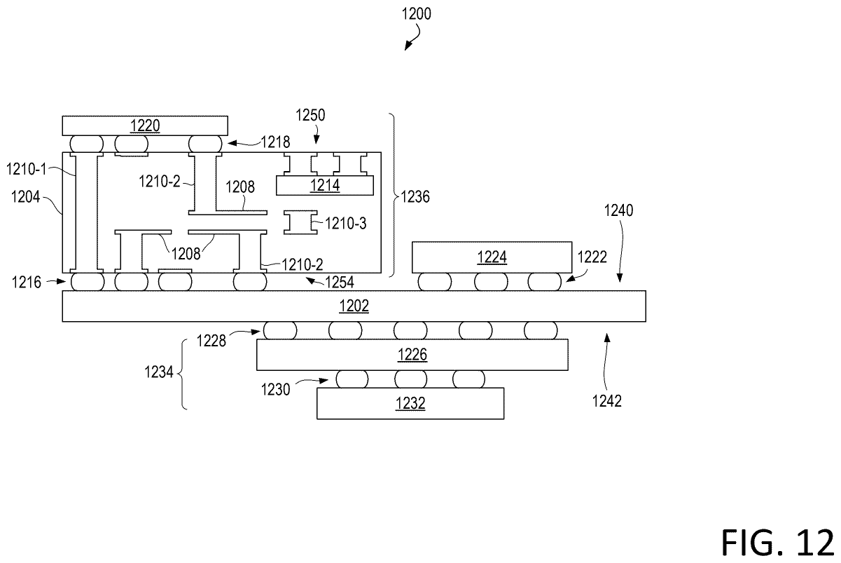

FIG. 12 is a cross-sectional side view of an integrated circuit device assembly 1200 that may include via doublets as disclosed herein. In some embodiments, the integrated circuit device assembly 1200 may be a microelectronic assembly. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpackaged integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art.

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include via doublets as disclosed herein. For example, any suitable components of the electrical device 1300 may include one or more of the integrated circuit device assemblies 1200, integrated circuit components 1220, integrated circuit devices 1000, integrated circuit dies 902, or other components disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as amplitude modulation (AM) or frequency modulation (FM) radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an integrated circuit device comprising a first interconnect layer comprising a first interconnect line and a third interconnect line; a second interconnect layer comprising a third interconnect line and a fourth interconnect line, wherein the second interconnect layer is over the first interconnect layer; a first via connecting the first interconnect line to the third interconnect line, wherein the first via has a first substantially rectangular cross section at a bottom of the first via and a second substantially rectangular cross section at a top of the first via, a first side surface that is seamless with a side surface of the first interconnect line, and a second side surface that is seamless with a side surface of the third interconnect line; and a second via adjacent to the first via, the second via connecting the second interconnect line to the fourth interconnect line, wherein the second via has a first substantially rectangular cross section at a bottom of the second via and a second substantially rectangular cross section at a top of the second via, a first side surface that is seamless with a side surface of the second interconnect line, and a second side surface that is seamless with a side surface of the fourth interconnect line.

Example 2 includes the subject matter of Example 1, and wherein the first via has a third side surface opposite the first side surface of the first via, wherein the third side surface of the first via is seamless with a second side surface of the first interconnect line.

Example 3 includes the subject matter of any of Examples 1 and 2, and wherein the first via has a third side surface opposite the second side surface of the first via, wherein the third side surface of the first via is seamless with a second side surface of the third interconnect line.

Example 4 includes the subject matter of any of Examples 1-3, and wherein the first interconnect line comprises a conductive etch stop material at a top of the first interconnect line.

Example 5 includes the subject matter of any of Examples 1-4, and wherein the first interconnect line predominantly comprises a conductive material that is different from the conductive etch stop material.

Example 6 includes the subject matter of any of Examples 1-5, and wherein the conductive etch stop material comprises at least one of tungsten, ruthenium, titanium nitride, tantalum, and tantalum nitride.

Example 7 includes the subject matter of any of Examples 1-6, and wherein the third interconnect line comprises a conductive etch stop material at a bottom of the third interconnect line.

Example 8 includes the subject matter of any of Examples 1-7, and wherein the third interconnect line predominantly comprises a conductive material that is different from the conductive etch stop material.

Example 9 includes the subject matter of any of Examples 1-8, and wherein a pitch between the first via and the second via is less than 20 nanometers.

Example 10 includes the subject matter of any of Examples 1-9, and wherein a pitch between the first via and the second via is substantially equal to a pitch between adjacent interconnect lines of the first interconnect layer.

Example 11 includes the subject matter of any of Examples 1-10, and further including an integrated circuit die comprising the first interconnect layer, second interconnect layer, first via, and second via.

Example 12 includes the subject matter of any of Examples 1-11, and further including a circuit board coupled to the integrated circuit die.

Example 13 includes the subject matter of any of Examples 1-12, and further including at least one of a network interface, battery, or memory coupled to the integrated circuit die.

Example 14 includes an apparatus comprising a first interconnect layer comprising a first interconnect line and a second interconnect line adjacent to and substantially parallel with the first interconnect line; a second interconnect layer over the first interconnect layer, the second interconnect layer comprising a third interconnect line and a fourth interconnect line that is inline with the third interconnect line; a first via connected to the first interconnect line and the third interconnect line, wherein the first via has a side surface that is substantially coplanar with a side surface of the first interconnect line at an interface between the side surface of the first via and the side surface of the first interconnect line; and a second via connected to the second interconnect line and the fourth interconnect line, wherein the second via has a side surface that is substantially coplanar with a side surface of the second interconnect line at an interface between the side surface of the second via and the side surface of the second interconnect line.

Example 15 includes the subject matter of Example 14, and wherein the first via has a second side surface that is substantially coplanar with a side surface of the second interconnect line at an interface between the second side surface of the first via and the side surface of the second interconnect line.

Example 16 includes the subject matter of any of Examples 14 and 15, and wherein the side surface of the first via is laterally offset from a bottom of a side surface of the third interconnect line.

Example 17 includes the subject matter of any of Examples 14-16, and wherein the first via has a first substantially rectangular cross section at a top of the first via and a second substantially rectangular cross section at a bottom of the first via.

Example 18 includes the subject matter of any of Examples 14-17, and wherein the second via has a first substantially rectangular cross section at a top of the second via and a second substantially rectangular cross section at a bottom of the second via.

Example 19 includes the subject matter of any of Examples 14-18, and further including a conductive etch stop material on top of the first interconnect layer.

Example 20 includes the subject matter of any of Examples 14-19, and wherein the conductive etch stop material predominately comprises a conductive material that is different from a conductive material of the first interconnect layer.

Example 21 includes the subject matter of any of Examples 14-20, and wherein the conductive etch stop material comprises at least one of tungsten, ruthenium, titanium nitride, tantalum, and tantalum nitride.

Example 22 includes the subject matter of any of Examples 14-21, and further including a conductive etch stop material at the bottom of the second interconnect layer.

Example 23 includes the subject matter of any of Examples 14-22, and wherein the conductive etch stop material predominately comprises a conductive material that is different from a conductive material of the second interconnect layer.

Example 24 includes the subject matter of any of Examples 14-23, and wherein a pitch between the first via and the second via is less than 20 nanometers.

Example 25 includes the subject matter of any of Examples 14-24, and wherein a pitch between the first via and the second via is substantially equal to a pitch between adjacent interconnect lines of the first interconnect layer.

Example 26 includes the subject matter of any of Examples 14-25, and further including an integrated circuit die comprising the first interconnect layer, second interconnect layer, and via.

Example 27 includes the subject matter of any of Examples 14-26, and further including a circuit board coupled to the integrated circuit die.

Example 28 includes the subject matter of any of Examples 14-27, and further including at least one of a network interface, battery, or memory coupled to the integrated circuit die.

Example 29 includes a method comprising forming a first layer; forming a second layer over the first layer; and applying an etch material to concurrently form a first interconnect line and a second interconnect line in the first layer and side surfaces of a first via and a second via in the second layer, wherein a side surface of the first via is seamless with a side surface of the first interconnect line, wherein a side surface of the second via is seamless with a side surface of the second interconnect line, wherein the first via is adjacent to the second via.

Example 30 includes the subject matter of Example 29, and further including forming a third layer over the second layer; and applying a second etch material to concurrently form an interconnect line in the third layer, a second side surface of the first via, and a second side surface of the second via, wherein the second side surface of the first via and the second side surface of the second via are seamless with a side surface of the interconnect line of the third layer.

Example 31 includes the subject matter of any of Examples 29-30, and further including applying a third etch material to etch through the interconnect line of the third layer to form a first interconnect line and a second interconnect line in the third layer, wherein the first via is connected to the first interconnect line and the second layer is connected to the second interconnect line.

Example 32 includes the subject matter of any of Examples 29-31, and wherein forming the third layer comprises depositing a conductive etch stop material on the second layer and depositing a conductive material on the conductive etch stop material.

Example 33 includes the subject matter of any of Examples 29-32, and wherein the first via has a second side surface that is substantially coplanar with a side surface of the second interconnect line at an interface between the second side surface of the first via and the side surface of the second interconnect line.

Example 34 includes the subject matter of any of Examples 29-33, and wherein the side surface of the first via is laterally offset from a bottom of a side surface of the third interconnect line.

Example 35 includes the subject matter of any of Examples 29-34, and wherein the first via has a first substantially rectangular cross section at a top of the first via and a second substantially rectangular cross section at a bottom of the first via.

Example 36 includes the subject matter of any of Examples 29-35, and wherein the second via has a first substantially rectangular cross section at a top of the second via and a second substantially rectangular cross section at a bottom of the second via.

Example 37 includes the subject matter of any of Examples 29-36, and further including forming a conductive etch stop material on top of the first layer.

Example 38 includes the subject matter of any of Examples 29-37, and wherein the conductive etch stop material predominately comprises a conductive material that is different from a conductive material of the first layer.

Example 39 includes the subject matter of any of Examples 29-38, and wherein the conductive etch stop material comprises at least one of tungsten, ruthenium, titanium nitride, tantalum, and tantalum nitride.

Example 40 includes the subject matter of any of Examples 29-39, and wherein the conductive etch stop material on the second layer predominately comprises a conductive material that is different from a conductive material on the conductive etch stop material.

Example 41 includes the subject matter of any of Examples 29-40, and wherein a pitch between the first via and the second via is less than 20 nanometers.

Example 42 includes the subject matter of any of Examples 29-41, and wherein a pitch between the first via and the second via is substantially equal to a pitch between adjacent interconnect lines of the first layer.

Example 43 includes the subject matter of any of Examples 29-42, and further including forming an integrated circuit die comprising the first layer, second layer, first via, and second via.

Example 44 includes the subject matter of any of Examples 29-43, and further including coupling the integrated circuit die to a circuit board.

Example 45 includes the subject matter of any of Examples 29-44, and further including coupling at least one of a network interface, battery, or memory coupled to the integrated circuit die.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An integrated circuit device comprising:
a first interconnect layer comprising a first interconnect line and a second interconnect line;
a second interconnect layer comprising a third interconnect line and a fourth interconnect line, wherein the second interconnect layer is over the first interconnect layer;
a first via connecting the first interconnect line to the third interconnect line, wherein the first via has a first substantially rectangular cross section at a bottom of the first via and a second substantially rectangular cross section at a top of the first via, a first side surface that is seamless with a side surface of the first interconnect line, and a second side surface that is seamless with a side surface of the third interconnect line; and
a second via adjacent to the first via, the second via connecting the second interconnect line to the fourth interconnect line, wherein the second via has a first substantially rectangular cross section at a bottom of the second via and a second substantially rectangular cross section at a top of the second via, a first side surface that is seamless with a side surface of the second interconnect line, and a second side surface that is seamless with a side surface of the fourth interconnect line.

2. The integrated circuit device of claim 1, wherein the first via has a third side surface opposite the first side surface of the first via, wherein the third side surface of the first via is seamless with a second side surface of the first interconnect line.

3. The integrated circuit device of claim 1, wherein the first via has a third side surface opposite the second side surface of the first via, wherein the third side surface of the first via is seamless with a second side surface of the third interconnect line.

4. The integrated circuit device of claim 1, wherein the first interconnect line comprises a conductive etch stop material at a top of the first interconnect line.

5. The integrated circuit device of claim 4, wherein the first interconnect line predominantly comprises a conductive material that is different from the conductive etch stop material.

6. The integrated circuit device of claim 4, wherein the conductive etch stop material comprises at least one of tungsten, ruthenium, titanium nitride, tantalum, and tantalum nitride.

7. The integrated circuit device of claim 1, wherein the third interconnect line comprises a conductive etch stop material at a bottom of the third interconnect line.

8. The integrated circuit device of claim 7, wherein the third interconnect line predominantly comprises a conductive material that is different from the conductive etch stop material.

9. The integrated circuit device of claim 1, wherein a pitch between the first via and the second via is less than 20 nanometers.

10. The integrated circuit device of claim 1, wherein a pitch between the first via and the second via is substantially equal to a pitch between adjacent interconnect lines of the first interconnect layer.

11. The integrated circuit device of claim 1, further comprising an integrated circuit die comprising the first interconnect layer, second interconnect layer, first via, and second via.

12. The integrated circuit device of claim 11, further comprising a circuit board coupled to the integrated circuit die.

13. The integrated circuit device of claim 11, further comprising at least one of a network interface, battery, or memory coupled to the integrated circuit die.

14. An apparatus comprising:
a first interconnect layer comprising a first interconnect line and a second interconnect line adjacent to and substantially parallel with the first interconnect line;
a second interconnect layer over the first interconnect layer, the second interconnect layer comprising a third interconnect line and a fourth interconnect line that is inline with the third interconnect line;
a first via connected to the first interconnect line and the third interconnect line, wherein the first via has a side surface that is substantially coplanar with a side surface of the first interconnect line at an interface between the side surface of the first via and the side surface of the first interconnect line; and
a second via connected to the second interconnect line and the fourth interconnect line, wherein the second via has a side surface that is substantially coplanar with a side surface of the second interconnect line at an interface between the side surface of the second via and the side surface of the second interconnect line.

15. The apparatus of claim 14, wherein the first via has a second side surface that is substantially coplanar with a side surface of the second interconnect line at an interface between the second side surface of the first via and the side surface of the second interconnect line.

16. The apparatus of claim 15, wherein the side surface of the first via is laterally offset from a bottom of a side surface of the third interconnect line.

17. A method comprising:
forming a first layer;
forming a second layer over the first layer; and
applying an etch material to concurrently form a first interconnect line and a second interconnect line in the first layer and side surfaces of a first via and a second via in the second layer, wherein a side surface of the first via is seamless with a side surface of the first interconnect line, wherein a side surface of the second via is seamless with a side surface of the second interconnect line, wherein the first via is adjacent to the second via.

18. The method of claim 17, further comprising:
forming a third layer over the second layer; and
applying a second etch material to concurrently form an interconnect line in the third layer, a second side surface of the first via, and a second side surface of the second via, wherein the second side surface of the first via and the second side surface of the second via are seamless with a side surface of the interconnect line of the third layer.

19. The method of claim 18, further comprising applying a third etch material to etch through the interconnect line of the third layer to form a first interconnect line and a second interconnect line in the third layer, wherein the first via is connected to the first interconnect line and the second layer is connected to the second interconnect line.

20. The method of claim 18, wherein forming the third layer comprises depositing a conductive etch stop material on the second layer and depositing a conductive material on the conductive etch stop material.
